(19) United States
(12) Patent Application Publication
(10) Pub. No.: US 2009/0260680 A1
(43) Pub. Date: Oct. 22, 2009

(54) Photovoltaic Devices and Associated Methods

(76) Inventor: Chien-Min Sung, Taipei County (TW)

Correspondence Address: THORPE NORTH & WESTERN, LLP., P.O. Box 1219, SANDY, UT, 84091-1219, US

(21) Appl. No.: 12/390,060

(22) Filed: Feb. 20, 2009

Related U.S. Application Data
(60) Provisional application No. 61/031,606, filed on Feb. 26, 2008.

(51) Int. Cl. H01L 31/028; H01L 29/12; H01L 21/04

(52) U.S. Cl. 136/255; 257/77; 438/105; 257/E29.068; 257/E21.042; 257/E31.011

(57) ABSTRACT

Materials, devices, and methods for enhancing performance of electronic devices such as solar cells, thermoelectric conversion devices and other electronic devices are provided. In one aspect, for example, an electronic device is provided. Such a device may include a charge carrier separation layer further including a layer of a P-type material comprising copper, gallium, indium and at least one member selected from the group consisting of selenide and sulfide, and a layer of an N-type material adjacent to the P-type material, where the N-type material includes diamond-like carbon doped with an N dopant. The electronic device may further include a first electrode adjacent to the layer of P-type material of the charge carrier separation layer opposite to the N-type material.

This application claims the benefit of U.S. Provisional Patent Application Ser. No. 61/031,606, filed on Feb. 26, 2008, which is incorporated herein by reference.

### FIELD OF THE INVENTION

The present invention relates generally to photovoltaic devices and methods that utilize conductive diamond-like carbon materials. Accordingly, the present application involves the fields of physics, chemistry, electricity, and material science.

### BACKGROUND OF THE INVENTION

Solar cell technologies have progressed over the past several decades resulting in a significant contribution to potential power sources in many different applications. Despite dramatic improvements in materials and manufacturing methods, solar cells still have efficiency limits well below theoretical efficiencies. Various approaches have attempted to increase efficiencies with some success. For example, prior approaches have included light trapping structures and buried electrodes in order to minimize surface area shaded by the conductive metal grid. Other methods have included a rear contact configuration where recombination of hole-electron pairs occurs along the rear side of the cell.

However, these and other approaches still suffer from drawbacks such as mediocre efficiencies, manufacturing complexities, material costs, reliability, and radiation degradation, among others.

### SUMMARY OF THE INVENTION

Accordingly, the present invention provides materials, devices, and methods for enhancing performance of electronic devices such as solar cells, thermoelectric conversion devices and other electronic devices. In one aspect, for example, an electronic device is provided. Such a device may include a charge carrier separation layer further including a layer of a P-type material comprising copper, gallium, indium and at least one member selected from the group consisting of selenide and sulfide, and a layer of an N-type material adjacent to the P-type material, where the N-type material includes diamond-like carbon doped with an N dopant. The electronic device may further include a first electrode adjacent to the layer of P-type material of the charge carrier separation layer opposite to the N-type material.

A variety of diamond materials may be utilized in the electronic devices according to aspects of the present invention. In one aspect, for example, the diamond-like carbon may be conductive diamond-like carbon. In one specific aspect, the conductive diamond-like carbon may have an sp³ bonded carbon content from about 30 atom % to about 90 atom %, a hydrogen content from O atom % to about 30 atom %, and an sp² bonded carbon content from about 10 atom % to about 70 atom %. In another specific aspect, the sp² bonded carbon content may be sufficient to provide the conductive diamond-like carbon material with a visible light transmissivity of greater than about 0.70. In yet another specific aspect, the sp² bonded carbon content may be from about 35 atom % to about 60 atom %. In a further specific aspect, the hydrogen content may be from about 15 atom % to about 25 atom %. Additionally, in another aspect, the conductive diamond-like carbon material may be conductive amorphous diamond.

In another aspect of the present invention, a second electrode may be included adjacent to the layer of N-type material of the charge carrier separation layer opposite to the P-type material. Although numerous materials are contemplated, in one aspect the second electrode may include a material such as indium tin oxide, doped zinc oxide, fluorine-doped tin oxide, and combinations thereof.

Although the charge carrier separation layers of the present invention may be of any thickness, the combination of materials disclosed herein are particularly suited for thin flexible electronic devices. Non-limiting examples of such devices may include flexible solar cells and multi-junction solar cells. In one aspect, the charge carrier separation layer may have a thickness of from about 1 μm to about 50 μm. In another aspect, the charge carrier separation layer may have a thickness of from about 1 μm to about 5 μm. In yet another aspect, the charge carrier separation layer may have a thickness that is less than about 3 μm.

The present invention additionally provides aspects directed to charge carrier separation layers. In one aspect, for example, a charge carrier separation layer may include a layer of a P-type material comprising copper, gallium, indium and at least one of selenide or sulfide, and a layer of an N-type material adjacent to the P-type material, where the N-type material including diamond-like carbon doped with an N dopant.

The present invention also provides methods for making electronic devices. In one aspect, for example, a method of forming a flexible electronic device may include coating a layer of diamond-like carbon onto substrate, doping the layer of diamond-like carbon with an N dopant to form an N-type material layer, and applying a layer of a P-type material to the diamond-like carbon layer, wherein the P-type material includes copper, gallium, indium and at least one member selected from the group consisting of selenide and sulfide. The method may additionally include applying a first electrode to the layer of P-type material layer opposite to the N-type material layer.

In one specific aspect, applying the layer of a P-type material may further includes depositing a first mixture of indium, gallium, and selenide onto the diamond-like carbon layer, depositing mixture of copper and selenide onto the first mixture of indium, gallium, and selenide, and depositing a second mixture of indium, gallium, and selenide onto the mixture of copper and selenide.

In another aspect of the present invention, an electronic device is provided. Such a device may comprise a charge carrier separation layer including a layer of a P-type material comprising a first component selected from the group consisting of at least one of copper, gold, and silver, a second component selected from the group consisting of at least one of aluminum, gallium, and indium, and a third component selected from the group consisting of at least one of sulfur, selenium, tellurium, and oxygen, wherein the P-type material is tetrahedrally bonded. The charge carrier separation may further include a layer of an N-type material adjacent to the P-type material, where the N-type material includes diamond-like carbon doped with an N dopant, and a first electrode adjacent to the layer of P-type material of the charge carrier separation layer opposite to the N-type material.

There has thus been outlined, rather broadly, the more important features of the invention so that the detailed description thereof that follows may be better understood, and so that the present contribution to the art may be better appreciated. Other features of the present invention will become clearer from the following detailed description of the invention, taken with the accompanying drawings and claims, or may be learned by the practice of the invention.

### BRIEF DESCRIPTION OF THE DRAWINGS

FIG. 1 shows a side cross-sectional view of a conventional silicon solar cell in accordance with the prior art.

FIG. 2 shows an illustration of a diamond-like carbon device in accordance with one embodiment of the present invention.

FIG. 3 shows an illustration of a diamond-like carbon device in accordance with another embodiment of the present invention.

FIG. 4 shows an illustration of a diamond-like carbon device in accordance with yet another embodiment of the present invention.

The drawings will be described further in connection with the following detailed description. Further, these drawings are not necessarily to scale and are by way of illustration only such that dimensions and geometries can vary from those illustrated.

### DETAILED DESCRIPTION

Before the present invention is disclosed and described, it is to be understood that this invention is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

It must be noted that, as used in this specification and the appended claims, the singular forms “a,” “an,” and “the” include plural referents unless the context clearly dictates otherwise. Thus, for example, reference to “a layer” includes one or more of such layers, reference to “an additive” includes reference to one or more of such materials, and reference to “a cathodic arc technique” includes reference to one or more of such techniques.

### DEFINITIONS

In describing and claiming the present invention, the following terminology will be used in accordance with the definitions set forth below.

As used herein, “charge carrier separation layer” refers to any material or layer which provides an electric potential barrier to free electron flow. Non-limiting examples of charge carrier separation layers can include p-n junctions, p-i-n junctions, electrolyte solutions, thin film junctions (e.g. thin dielectric films), and the like.

As used herein, “electrode” refers to a conductor used to make electrical contact between at least two points in a circuit.

As used herein, “sp³ bonded carbon” refers to carbon atoms bonded to neighboring carbon atoms in a crystal structure substantially corresponding to the diamond isotope of carbon (i.e. pure sp³ bonding), and further encompasses carbon atoms arranged in a distorted tetrahedral coordination sp³ bonding, such as amorphous diamond and diamond-like carbon.

As used herein, “sp² bonded carbon” refers to carbon atoms bonded to neighboring carbon atoms in a crystal structure substantially corresponding to the graphitic isotope of carbon.

As used herein, “diamond” refers to a crystalline structure of carbon atoms bonded to other carbon atoms in a lattice of tetrahedral coordination known as sp³ bonding. Specifically, each carbon atom is surrounded by and bonded to four other carbon atoms, each located on the tip of a regular tetrahedron. Further, the bond length between any two carbon atoms is 1.54 angstroms at ambient temperature conditions, and the angle between any two bonds is 109 degrees, 28 minutes, and 16 seconds although experimental results may vary slightly. The structure and nature of diamond, including many of its physical and electrical properties are well known in the art.

As used herein, “distorted tetrahedral coordination” refers to a tetrahedral bonding configuration of carbon atoms that is irregular, or has deviated from the normal tetrahedron configuration of diamond as described above. Such distortion generally results in lengthening of some bonds and shortening of others, as well as the variation of the bond angles between the bonds. Additionally, the distortion of the tetrahedron alters the characteristics and properties of the carbon to effectively lie between the characteristics of carbon bonded in sp³ configuration (i.e. diamond) and carbon bonded in sp² configuration (i.e. graphite). One example of material having carbon atoms bonded in distorted tetrahedral bonding is amorphous diamond. It will be understood that many possible distorted tetrahedral configurations exist and a wide variety of distorted configurations are generally present in amorphous diamond.

As used herein, “diamond-like carbon” refers to a carbonaceous material having carbon atoms as the majority element, with a substantial amount of such carbon atoms bonded in distorted tetrahedral coordination. Diamond-like carbon (DLC) can typically be formed by PVD processes, although CVD or other processes could be used such as vapor deposition processes. In some aspects, diamond-like carbon may refer to nanocrystalline diamond materials. Notably, a variety of other elements can be included in the DLC material as either impurities, or as dopants, including without limitation, hydrogen, sulfur, phosphorous, boron, nitrogen, silicon, tungsten, etc.

As used herein, “amorphous diamond” refers to a type of diamond-like carbon having carbon atoms as the majority element, with a substantial amount of such carbon atoms bonded in distorted tetrahedral coordination. In one aspect, the amount of carbon in the amorphous diamond can be at least about 90%, with at least about 20% of such carbon being bonded in distorted tetrahedral coordination. Amorphous diamond also has a higher atomic density than that of diamond (176 atoms/cm³). Further, amorphous diamond and diamond materials contract upon melting.

As used herein, “transmissivity” refers to the portion of light which travels across a material. Transmissivity is defined as the ratio of the transmitted light intensity to the total incident light intensity and can range from 0 to 1.0.

As used herein, “vapor deposited” refers to materials which are formed using vapor deposition techniques. “Vapor deposition” refers to a process of depositing materials on a substrate through the vapor phase. Vapor deposition processes can include any process such as, but not limited to, chemical vapor deposition (CVD) and physical vapor deposition (PVD). A wide variety of variations of each vapor deposition method can be performed by those skilled in the art. Examples of vapor deposition methods include hot filament CVD, rf-CVD, laser CVD (LCVD), laser ablation, conformal diamond coating processes, metal-organic CVD (MOCVD), sputtering, thermal evaporation PVD, ionized metal PVD (IMPVD), electron beam PVD (EBPVD), reactive PVD, and the like.

As used herein, “asperity” refers to the roughness of a surface as assessed by various characteristics of the surface anatomy. Various measurements may be used as an indicator of surface asperity, such as the height of peaks or projections thereon, and the depth of valleys or concavities depressing therein. Further, measures of asperity include the number of peaks or valleys within a given area of the surface (i.e. peak or valley density), and the distance between such peaks or valleys.

As used herein, “metallic” refers to a metal, or an alloy of two or more metals. A wide variety of metallic materials are known to those skilled in the art, such as aluminum, copper, chromium, iron, steel, stainless steel, titanium, tungsten, zinc, zirconium, molybdenum, etc., including alloys and compounds thereof.

As used herein, “dielectric” refers to any material which is electrically resistive. Dielectric materials can include any number of types of materials such as, but not limited to, glass, polymers, ceramics, graphites, alkaline and alkali earth metal salts, and combinations or composites thereof.

As used herein, “electrically coupled” refers to a relationship between structures that allows electrical current to flow at least partially between them. This definition is intended to include aspects where the structures are in physical contact and those aspects where the structures are not in physical contact. Typically, two materials which are electrically coupled can have an electrical potential or actual current between the two materials. For example, two plates physically connected together by a resistor are in physical contact, and thus allow electrical current to flow between them. Conversely, two plates separated by a dielectric material are not in physical contact, but, when connected to an alternating current source, allow electrical current to flow between them by capacitive means. Moreover, depending on the insulative nature of the dielectric material, electrons may be allowed to bore through, or jump across the dielectric material when enough energy is applied.

As used herein, “adjacent” refers to near or close sufficient to achieve a desired affect. Although direct physical contact is most common and preferred in the layers of the present invention, adjacent can broadly allow for spaced apart features.

As used herein, “thermoelectric conversion” relates to the conversion of thermal energy to electrical energy or of electrical energy to thermal energy, or flow of thermal energy.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually. This same principle applies to ranges reciting only one numerical value as a minimum or a maximum. Furthermore, such an interpretation should apply regardless of the breadth of the range or the characteristics being described.

The Invention

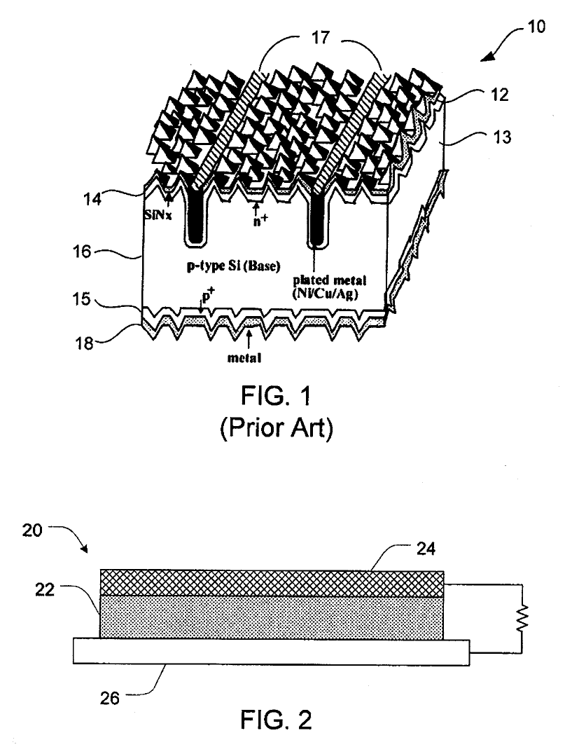

A variety of solar cell designs are known having a wide range of efficiencies. FIG. 1 illustrates one general example of a conventional crystalline silicon solar cell 10 in accordance with the prior art. An anti-reflection layer 12 is used to prevent excessive reflection of light from the surface of the underlying silicon layer 13. The anti-reflection layer is often an electrically insulating layer of silicon nitride, although other materials have also been used. The silicon solar cell shown in FIG. 1 is commonly referred to as a p-i-n solar cell due to the respective n and p doping of anode area 14 and cathode area 15 on either side of an insulating inner layer 16. A conductive metal grid 17 is buried into the silicon layer. The metal grid is typically formed of silver that is sintered at about 800° C., or in some cases can be other conductive metals like copper or nickel. The metal grid is embedded a significant distance into the insulating layer, e.g. typically over about 400 to 500 μm. A conductive metal such as silver or other suitable material is also used as the cathode 18. Although many other considerations are important in designing solar cells, such are well within the knowledge of one skilled in the art. Further, the above description provides a suitable background for the following discussion of various aspects of the present invention and the contribution thereof to the art.

Accordingly, the present invention provides photovoltaic devices having improved conversion efficiencies. As is illustrated in FIG. 2, in one aspect an electronic device 20 may be configured as a p-n junction. In such cases, an N-type material can be formed adjacent to a P-type material to form the charge carrier separation layer. More specifically, such a device may include a charge carrier separation layer including a layer of a P-type material 22 comprising copper, gallium, indium and at least one member selected from the group consisting of selenide and sulfide, and a layer of an N-type material 24 adjacent to the P-type material. In another aspect, the P-type material may include TiO₂, CdS, CdTe, etc. Furthermore, in yet another aspect the P-type materials may be tetrahedrally bonded.

The N-type material may be comprised of a layer of diamond-like carbon doped with an N dopant. Furthermore, the device may include a first electrode 26 adjacent to the layer of P-type material 22 of the charge carrier separation layer opposite to the N-type material 24.

Suitable N dopants may include, without limitation, nitrogen, phosphorous, lithium, arsenic, bismuth, antimony, and combinations thereof. Similarly it should be noted that the P-type material may be optionally doped with a P dopant, including, without limitation, boron, aluminum, gallium, indium, thallium, and combinations thereof. The degree of doping can be controlled by the conditions during doping such as dopant concentration, temperature, and the like. Thus the materials according to aspects of the present invention may be selectively doped using methods such as, but not limited to, ion implantation, drive-in diffusion, field-effect doping, electrochemical doping, vapor deposition, or the like. Further, such doping can be accomplished by co-deposition with the diamond-like carbon or semiconductor material. For example, a nitrogen source gas and carbon or other semiconductor source gas can be simultaneously present in a vapor deposition chamber.

Suitable charge separation carrier layers can be formed using a variety of methods such as, but not limited to, vapor deposition, epitaxial growth, or the like. In some aspects, a wafer may be used to create one or more of the described layers. Such a wafer can be cut from a solid silicon ingot or boule, and the wafer can be polished to have a smooth surface. Alternatively, the semiconductor or diamond-like carbon material can be formed directly on a desired substrate or electrode using vapor deposition or other suitable techniques. Further, the semiconductor or diamond surface can be etched to roughen the surface and/or may include features such as pyramidal depressions or extensions which increase functional surface areas of the device.

The diamond-like carbon electronic devices of the present invention allow for a significant reduction in the thickness of the charge carrier separation layer. At least one reason for this is the elimination or reduction of any buried metal grid electrodes. Thus the diamond-like carbon layers of the present invention allow for the semiconductor layer to be substantially planar and/or flexible. For example, the devices of the present invention can be free of trenches and/or metal grid materials which are present in conventional silicon solar cells. Although any thickness is contemplated, in one aspect, the charge carrier separation layer may have a thickness of from about 1 μm to about 50 μm. In another aspect, the charge carrier separation layer may have a thickness of from about 1 μm to about 5 μm. In yet another aspect, the charge carrier separation layer may have a thickness that is less than about 3 μm. Additionally, the use of diamond-like carbon material may also prevent these thinner semiconductor layers from warping.

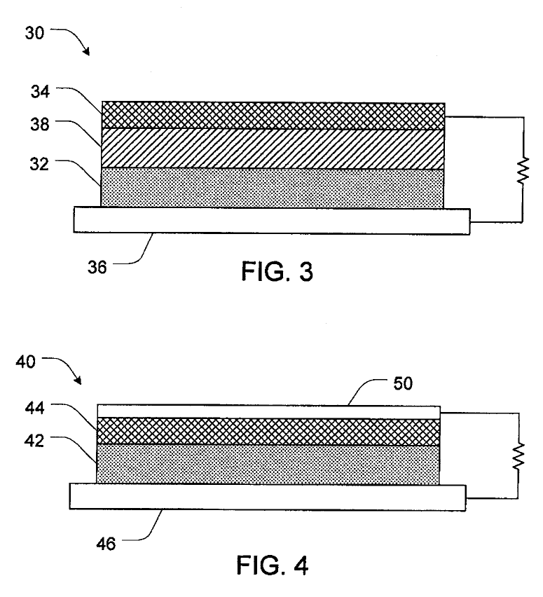

The present invention also contemplates charge carrier separation layers configured as a p-i-n junction. For example, FIG. 3 illustrates a p-i-n junction-type device 30 where the charge carrier separation layer includes a layer of a P-type material 32 comprising copper, gallium, indium and at least one member selected from the group consisting of selenide and sulfide, and a layer of an N-type material 34. The N-type material may be comprised of a layer of diamond-like carbon doped with an N dopant, and a first electrode 36 adjacent to the layer of P-type material 32 of the charge carrier separation layer opposite to the N-type material 34. Furthermore, a layer of an insulating material 38 may be disposed between the P-type material 32 and the N-type material 34 to improve the charge separation characteristics of the materials. The insulating material may be any dielectric material known to one of ordinary skill in the art. In one specific aspect, the insulating material may be a layer of hydrogenated diamond-like carbon or amorphous diamond.

The diamond-like carbon materials of the present invention can be useful for a variety of applications such as, but not limited to, solar cells, thermoelectric devices, or other applications, particularly where conductive and transparent electrodes are desired. Diamond-like carbon materials are useful in the devices of the present invention in part due to the radiation resistance, transparency, chemical inertness, and anti-reflective properties of such materials. For example, diamond-like carbon materials can have a visible light transmissivity from about 0.5 to about 1.0. Additionally, in some aspects the diamond-like carbon materials can be conductive. The conductivity and visible light transmissivity may be a function of sp² and sp³ bonded carbon content, hydrogen content, and optional conductive additives. For example, an increase in sp² bonded carbon content can increase conductivity while decreasing transmissivity. Conversely, an increase in hydrogen content and/or sp³ bonded carbon content can lead to increases in transmissivity and decrease in conductivity. Conductivity and transmissivity can also be affected by introduction of additives such as dopants or conductive materials.

In one aspect, the diamond-like carbon material may be electrically conductive, and can optionally function as an electrode. For example, a diamond-like carbon layer can include a diamond-like carbon material having a resistivity from about 0 μΩ-cm to about 80 μΩ-cm at 20° C., such that the material is electrically conductive. In another aspect the resistivity of the conductive diamond-like carbon material can be from about 0 μΩ-cm to about 40 μΩ-cm. In one aspect, such conductive diamond-like materials may have an sp³ bonded carbon content from about 30 atom % to about 90 atom %, a hydrogen content from O atom % to about 30 atom %, and an sp² bonded carbon content from about 10 atom % to about 70 atom %. At higher sp³ bonded carbon contents, e.g. from about 50 atom % to about 90 atom %, additional additives and/or dopants can be introduced to increase conductivity sufficient for use of the material as a conductive electrode within the device. For example, doping with nitrogen or other similar dopants can provide good results without significantly decreasing transmissivity. Conductivity may also be increased by including carbon nanotubes or nanometal particles in the diamond-like carbon material. Additionally, in one specific embodiment, the diamond-like carbon material may be amorphous diamond.

Further, sp² bonded carbon content can also contribute to increased transmissivity. However, similar to hydrogen content, sp² bonded carbon is graphitic in crystal structure and is non-conductive. Therefore, an appropriate balance of sp² bonded carbon content should be considered. As a general guideline, in one aspect the diamond-like carbon material can have from about 10 atom % to about 70 atom % sp² bonded carbon content. In another aspect, the conductive diamond-like carbon material can have from about 35 atom % to about 60 atom %. However, the specific content can depend on the hydrogen content, sp³ bonded carbon content, and other optional additives and/or dopants. The sp² bonded carbon content can preferably be sufficient to provide the diamond-like carbon material with a visible light transmissivity of greater than about 0.70, and most preferably greater than about 0.90.

The diamond-like carbon material of the present invention thus represents a distinct class of diamond-like carbon materials having the properties identified herein such as low resistivity, high transmissivity, etc. As mentioned earlier, these properties are at least partially related to variables such as hydrogen content, sp² and sp³ bonded carbon content, and optional additives or dopants. In many cases, the conductive diamond-like material can be formed on a support layer by a suitable vapor deposition process.

As has been suggested, increased hydrogen content may contribute to an increase in transmissivity. The hydrogen content can be incorporated throughout the diamond-like material or substantially only at a surface thereof. In one aspect, any hydrogen content can be substantially only at external surfaces of the conductive diamond-like material. In one specific aspect, the hydrogen content can range from O atom % to about 30 atom %. In another specific aspect, the hydrogen content can range from about 15 atom % to about 25 atom %. Additionally, in one alternative aspect, the conductive diamond-like carbon can be substantially free of hydrogen content. Hydrogen content can be increased by increasing hydrogen gas concentrations during deposition of the diamond-like carbon material. Alternatively, a diamond-like carbon material can be heat treated with hydrogen gas to form a hydrogen terminated surface layer of diamond-like carbon. As an example, deposition may occur using a vapor deposition process such as chemical vapor deposition, although other methods can be suitable.

Increased hydrogen content can also be accompanied by decreased conductivity. Therefore, in some aspects it may be desirable to introduce a conductive additive in relatively small amounts to increased conductivity. For example, conductive metal particulates can be incorporated into the hydrogenated diamond-like carbon material. Further, in order to avoid excessive decrease in transmissivity due to the metal particles, the size and/or the concentration of the particles can be decreased. Suitable metal particles can comprise metals such as silver, copper, or other similar materials. Such particulates can be any suitable size, although about 1 nm to about 1 μm is typically suitable with about 2 nm to about 100 nm being suitable and about 0.1 μm to about 0.6 μm being preferred. Smaller particle sizes allow for increased transmissivity but also may result in a contrasting decrease in contribution to conductivity of the diamond-like material. The concentration of metal additives can generally range from about 2 vol % to about 60 vol %, although optimal particle sizes and concentrations can vary considerably depending on the specific particle material, sp² and sp³ bonded carbon content, and hydrogen content.

Further, the electrode associated with the P-type material can be formed of any suitable conductive material. Non-limiting examples of suitable conductive materials can include silver, gold, tin, copper, aluminum, molybdenum, etc. Alternatively, at least a portion of the first electrode can be formed of a conductive diamond-like carbon material. Although the same parameters can be used as described above, transmissivity of the first electrode may be less important. Therefore, a higher sp² carbon bonded content can be tolerated than for the anode side without the need for additives or dopants.

The diamond-like carbon material can be made using any suitable method, such as various vapor deposition processes. In one aspect of the invention, for example, the diamond-like carbon material can be formed using a cathodic arc method. Various cathodic arc processes are well known to those of ordinary skill in the art, such as those disclosed in U.S. Pat. Nos. 4,448,799; 4,511,593; 4,556,471; 4,620,913; 4,622,452; 5,294,322; 5,458,754; and 6,139,964, each of which is incorporated herein by reference. Generally speaking, cathodic arc techniques involve the physical vapor deposition (PVD) of carbon atoms onto a target, or substrate. The arc is generated by passing a large current through a graphite electrode that serves as a cathode, and vaporizing carbon atoms with the current. If the carbon atoms contain a sufficient amount of energy (i.e. about 100 eV) they will impinge on the target and adhere to its surface to form a carbonaceous material, such as diamond-like carbon. diamond-like carbon can be coated on almost any metallic substrate, typically with no, or substantially reduced, contact resistance. In general, the kinetic energy of the impinging carbon atoms can be adjusted by the varying the negative bias at the substrate and the deposition rate can be controlled by the arc current. Control of these parameters as well as others can also adjust the degree of distortion of the carbon atom tetrahedral coordination and the geometry, or configuration of the diamond-like carbon material (i.e. for example, a high negative bias can accelerate carbon atoms and increase sp³ bonding). By measuring the Raman spectra of the material the sp³/sp² ratio can be determined. However, it should be kept in mind that the distorted tetrahedral portions of the diamond-like carbon material are generally neither pure sp³ nor sp² but a range of bonds which are of intermediate character. Further, increasing the arc current can increase the rate of target bombardment with high flux carbon ions. As a result, temperature can rise so that the deposited carbon will convert to more stable graphite. Thus, final configuration and composition (i.e. band gaps, NEA, and emission surface asperity) of the diamond-like carbon material can be controlled by manipulating the cathodic arc conditions under which the material is formed.

Additionally, other processes can be used to form diamond-like carbon such as various vapor deposition processes, e.g. chemical vapor deposition or the like. Chemical vapor deposition (CVD) of diamond-like carbon can generally be performed by introducing a carbon source gas at elevated temperatures into a chamber housing a deposition substrate, e.g. semiconductor or charge separation carrier layer. Diamond-like carbon is typically deposited using physical vapor deposition (PVD) which involves impinging carbon atoms against a substrate at relatively low deposition and plasma temperatures (e.g. 100° C.). Due to the low temperature of such PVD methods, carbon atoms are not located at thermal equilibrium positions. As a result, the film can be less stable with high internal stress. Alternatively, CVD processes can be employed to deposit diamond-like carbon. If the deposition temperature is high (e.g. 800° C.), diamond will grow to become a crystalline CVD diamond film. An example of a suitable CVD process is radio frequency (13.6 MHz) CVD by dissociation of acetylene (C₂H₂) and hydrogen gas under partial vacuum (millitorr). Alternatively, pulsed DC can be used in stead of RF CVD. In the case of amorphous diamond, deposition by cathodic arc or laser ablation can form a suitable layer.

In another aspect the diamond-like carbon material may be a nanocrystalline diamond layer. Such a material may be deposited by low temperature CVD. In one specific aspect, for example, a nanocrystalline layer may be made by diffusing the plasma energy of CVD to spread the deposition over a greater surface area.

The formation of the diamond-like carbon material may be further facilitated through conformal deposition techniques. Conformal diamond coating processes can provide a number of advantages over conventional diamond film processes. Conformal diamond coating can be performed on a wide variety of substrates, including non-planar substrates. A growth surface can be pretreated under diamond growth conditions in the absence of a bias to form a carbon film. The diamond growth conditions can be conditions which are conventional vapor deposition conditions for diamond without an applied bias. As a result, a thin carbon film can be formed which is typically less than about 100 angstroms. The pretreatment step can be performed at almost any growth temperature such as from about 200° C. to about 900° C., although lower temperatures below about 500° C. may be preferred. Without being bound to any particular theory, the thin carbon film appears to form within a short time, e.g., less than one hour, and is a hydrogen terminated amorphous carbon.

Following formation of the thin carbon film, the growth surface may then be subjected to diamond growth conditions to form the diamond-like carbon or amorphous diamond layer. The diamond growth conditions may be those conditions which are commonly used in traditional vapor deposition diamond growth. However, unlike conventional amorphous diamond film growth, the amorphous diamond film produced using the above pretreatment steps results in a conformal amorphous diamond film that typically begins growth substantially over the entire growth surface with substantially no incubation time.

It is also contemplated that, particularly for those aspects relating to solar cells, the upper exposed surface of the device can be configured to improve energy absorption. Specifically, the surface area of the outer layer of the device can be increased by forming features which extend outwardly, such as the pyramids or other protrusions. Such features not only increase the surface area for exposure to light or other energy sources, but also provide an increased junction surface area per total area of the device. Further, diamond-like carbon materials can have a surface roughness which further increases the surface area on a much smaller scale. The surface features such as pyramids can typically have dimensions in the tens of microns range, while the diamond-like carbon material can have asperities in the nanometer range. In one aspect, for example, the diamond-like carbon material can have a surface asperity having a height of from about 10 to about 10,000 nanometers. In another aspect, the diamond-like carbon material can have an asperity height of from about 10 to about 1,000 nanometers. In yet another aspect, the asperity height can be about 800 nanometers. In a further aspect, the asperity height can be about 100 nanometers. Further, in one aspect the asperities can have a peak density of at least about 1 million peaks per square centimeter of the surface. In another aspect, the peak density can be at least about 100 million peaks per square centimeter of the surface. In yet another aspect, the peak density can be at least about 1 billion peaks per square centimeter of the surface. In a further aspect, the asperity can include a height of about 800 nanometers and a peak density of at least about, or greater than about 1 million peaks per square centimeter of emission surface. In yet a further aspect, the asperity can include a height of about 1,000 nanometers and a peak density of at least about, or greater than 1 billion peaks per square centimeter of the surface.

As has been described, doped conductive diamond-like carbon can function as both the N-type material and the electrode associated with the N-type material. In some aspects, however, it may be beneficial to include a second electrode adjacent to the diamond-like carbon layer opposite to the P-type material. In such cases, the diamond-like carbon can be conductive or non-conductive. In order to improve the efficiency of the device, however, it may be beneficial to utilize a transparent material for the second electrode. Such transparent materials are well known in the art, and may include such non-limiting examples as indium tin oxide, doped zinc oxide, fluorine-doped tin oxide, etc.

FIG. 4 illustrates one example of a device 40 including a charge carrier separation layer having a layer of a P-type material 42 comprising copper, gallium, indium and at least one member selected from the group consisting of selenide and sulfide, and a layer of an N-type material 44. The N-type material may be comprised of a layer of diamond-like carbon doped with an N dopant, and a first electrode 46 adjacent to the layer of P-type material 42 of the charge carrier separation layer opposite to the N-type material 44. Furthermore, a second electrode 50 is located adjacent to the N-type material 44 opposite to the layer of P-type material 42. It should be noted devices including a second electrode can be configured as a p-n junction as shown, as a p-i-n junction, or as any other known junctional configuration for such devices.

In yet another aspect of the present invention, the charge carrier separation layer can form a multi-junction solar cell. Multiple junctions can be configured having a variation in bandgaps. Typically, a single junction is capable of absorbing light corresponding to a specific bandgap for the materials comprising the junction. By preparing and configuring multiple junctions in series across the device each junction can have a different bandgap. As a result, a larger percentage of incoming energy can be converted to useful work, e.g. electricity. The charge carrier separation layer can be multiple p-n and/or p-i-n junctions to form the multi-junction solar cell. The bandgap of each layer can be adjusted by varying dopant concentration, type and/or semiconductor material, e.g. silicon, gallium-based materials, or the like.

As an additional benefit of the present invention, the electrodes and the charge carrier separation layers can be formed or prepared at a temperature below about 750° C., and preferably below about 650° C. Such low temperature processing can prevent or significantly reduce warpage. Additionally, diamond-like carbon has a high radiation hardness such that it is resistant to aging and degradation over time. In contrast, typical semiconductor materials are UV degradable and tend to become less reliable over time. The use of amorphous or diamond-like carbon material has the further advantage of reducing thermal mismatch between layers of the device.

In an optional step, the diamond-like carbon electronic devices can be heat treated in a vacuum furnace. Heat treatment can improve the thermal and electrical properties across the boundaries between different materials. The diamond-like carbon electronic device can be subjected to a heat treatment to consolidate interfacial boundaries and reduce material defects. Typical heat treatment temperatures can range from about 200° C. to about 800° C. and more preferably from about 350° C. to about 500° C. depending on the specific materials chosen. Care should be taken to not over-vitrify the diamond materials, as such over-nitrification may cause an abundance of sp² bond formation that may interfere with the electrical properties of the material.

The present invention additionally provides methods for making the electronic devices of the present invention. In one aspect, for example, the P-type material may be formed on a layer of molybdenum that has been coated on a substrate such as silicon. The N-type material may then be coated onto the P-type material, or in some cases onto a dielectric layer coated on the P-type material. In another aspect, the N-type material may be formed on a suitable substrate, and the P-type material may be formed on the N-type material. A subsequent layer of molybdenum or other conductive material may then be applied to the P-type material to form the electrode. It should be noted that it may be beneficial to minimize the crystal dislocations and other lattice defects within and between layers to increase the efficiency of the devices.

It is contemplated that additional device structures may be utilized with the devices of the present invention. In one aspect, for example, a diamond electroluminescent device may be incorporated into a photovoltaic device to generate illumination. Such a device may be useful on low light or cloudy days. The diamond-like carbon materials of the present invention may be excited by infrared rays. The energy derived from these rays may be used to excite a phosphor layer of the electroluminescent device to thus produce illumination. Further description of such electroluminescent devices may be found in U.S. patent application Ser. No. 11/045,016, filed on Jan. 26, 2006, which is incorporated herein by reference.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. An electronic device, comprising:
a charge carrier separation layer including:
a layer of a P-type material comprising copper, gallium, indium and at least one member selected from the group consisting of selenide and sulfide;
a layer of an N-type material adjacent to the P-type material, the N-type material including diamond-like carbon doped with an N dopant; and
a first electrode adjacent to the layer of P-type material of the charge carrier separation layer opposite to the N-type material.

2. The device of claim 1, wherein the diamond-like carbon is conductive diamond-like carbon.

3. The device of claim 2, wherein the conductive diamond-like carbon has an sp³ bonded carbon content from about 30 atom % to about 90 atom %, a hydrogen content from O atom % to about 30 atom %, and an sp² bonded carbon content from about 10 atom % to about 70 atom %.

4. The device of claim 2, wherein the sp² bonded carbon content is sufficient to provide the conductive diamond-like carbon material with a visible light transmissivity of greater than about 0.70.

5. The device of claim 2, wherein the sp² bonded carbon content is from about 35 atom % to about 60 atom %.

6. The device of claim 2, wherein the hydrogen content is from about 15 atom % to about 25 atom %.

7. The device of claim 2, wherein the conductive diamond-like carbon material is conductive amorphous diamond.

8. The device of claim 1, further including a second electrode adjacent to the layer of N-type material of the charge carrier separation layer opposite to the P-type material.

9. The device of claim 8, wherein the second electrode is a member selected from the group consisting of indium tin oxide, doped zinc oxide, fluorine-doped tin oxide, and combinations thereof.

10. The device of claim 1, wherein the N dopant is a member selected from the group consisting of nitrogen, phosphorous, lithium, arsenic, bismuth, antimony, and combinations thereof.

11. The device of claim 1, wherein the flexible electronic device is a solar cell.

12. The device of claim 11, wherein the solar cell is a multi-junction solar cell.

13. The device of claim 1, wherein the charge carrier separation layer has a thickness from about 1 μm to about 50 μm.

14. The device of claim 1, wherein the charge carrier separation layer has a thickness from about 1 μm to about 5 μm.

15. The device of claim 1, wherein the charge carrier separation layer has a thickness that is less than about 3 μm.

16. A charge carrier separation layer, comprising:
a layer of a P-type material comprising copper, gallium, indium and at least one of selenide or sulfide; and
a layer of an N-type material adjacent to the P-type material, the N-type material including diamond-like carbon doped with an N dopant.

17. A method of forming an electronic device, comprising:
coating a layer of diamond-like carbon onto substrate;
doping the layer of diamond-like carbon with an N dopant to form an N-type material layer;
applying a layer of a P-type material to the diamond-like carbon layer, wherein the P-type material includes copper, gallium, indium and at least one member selected from the group consisting of selenide and sulfide; and
applying a first electrode to the layer of P-type material layer opposite to the N-type material layer.

18. The method of claim 17, further comprising removing the substrate from the diamond-like carbon layer.

19. The method of claim 17, wherein the substrate is a transparent second electrode.

20. An electronic device, comprising:
a charge carrier separation layer including:
a layer of a P-type material comprising a first component selected from the group consisting of at least one of copper, gold, and silver, a second component selected from the group consisting of at least one of aluminum, gallium, and indium, and a third component selected from the group consisting of at least one of sulfur, selenium, tellurium, and oxygen, wherein the P-type material is tetrahedrally bonded;
a layer of an N-type material adjacent to the P-type material, the N-type material including diamond-like carbon doped with an N dopant; and
a first electrode adjacent to the layer of P-type material of the charge carrier separation layer opposite to the N-type material.
